(19) United States
(12) Patent Application Publication
(10) Pub. No.: US 2008/0210162 A1
(43) Pub. Date: Sep. 4, 2008

(54) Substrate Processing Apparatus and Substrate Processing System

(75) Inventor: Toru Yonebayashi, Toyama (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC, TOKYO (JP)

(21) Appl. No.: 11/886,060

(22) PCT Filed: Mar. 23, 2006
(86) PCT No.: PCT/JP2006/305879

§ 371 Date: Sep. 11, 2007

(30) Foreign Application Priority Data
Mar. 29, 2005 (JP) 2005-095651

(51) Int. Cl. C23C 16/44

(52) U.S. Cl. 118/715

(57) ABSTRACT

In a substrate processing apparatus in which substrates are processed by an operator who prepares recipes on an operating screen displayed on a display means, and a processing means that performs the prepared recipes, a configuration is adopted so that a plurality of operating items relating to an adjustment operation involving the aforementioned substrate processing apparatus is displayed in order, and the recipes used in the aforementioned respective operating items during the aforementioned adjustment operations are displayed on the aforementioned operating screen.

### TECHNICAL FIELD

The present invention relates to a substrate processing apparatus and substrate processing system, and more particularly relates to a substrate processing apparatus and substrate processing system that are devised so that information relating to an adjustment operation involving the substrate processing apparatus is displayed on a display means.

### BACKGROUND ART

In general, vertical and horizontal substrate processing apparatuses and single-wafer substrate processing apparatuses are known as apparatuses for performing CVD, diffusion processing, and the like on substrates.

Conventionally, when adjustment operations (set-up operations) involving substrate processing apparatuses of these types are performed in a clean room in the plant, a operations manual is copied onto clean paper and carried into the clean room, and adjustment operations are performed in accordance with this operations manual. The adjustment operations include various operating items, and each time the operation involving one operating item is completed, an entry is made in the clean notes.

### DISCLOSURE OF THE INVENTION

### Problems which the Invention is Intended to Solve

However, because of differences in the content of the operating items, unification is difficult in the case of the clean note description method, and it is difficult to understand the operating conditions at a glance merely by looking at the descriptive contents of clean notes made by other persons. Accordingly, it is necessary to confirm the contents by directly asking the person in question. In this case, however, the operating efficiency is low, and it does not make any sense to perform adjustment operations by assembling a team that includes a plurality of responsible persons.

Consequently, an object of the present invention is to perform adjustment operations with good efficiency by informing the workers of the order of operations and the beginning and completion of operations in a manner that is easy to understand, and thus to perform the handover operations in an efficient manner when adjustment operations are performed on a substrate processing apparatus.

### Means Used to Solve the Problems

A first aspect of the present invention provides a substrate processing apparatus in which an operator prepares a recipe on an operating screen displayed on a display means, and processing of the substrate is performed by processing means for executing the prepared recipe, wherein this substrate processing apparatus is constructed so that a plurality of operating items relating to adjustment operations involving the aforementioned substrate processing apparatus is displayed in order, and that the recipe that is used in the aforementioned respective operating items is displayed on the aforementioned operating screen when the aforementioned adjustment operations are performed.

### EFFECT OF THE INVENTION

In the present invention, as is clear from the description given above, operating items relating to adjustment operations, the order of these operations, and the degree of progress of the operations can be grasped in adjustment operations performed on a substrate processing apparatus, and the adjustment operations can therefore be efficiently performed by a plurality of workers. The present invention is especially effective in cases in which the adjustment operations are handed off to other workers or in cases in which the operations are continued on the following day.

### BEST MODE FOR CARRYING OUT THE INVENTION

Below, embodiments of the semiconductor manufacturing apparatus of the present invention will be described in detail with reference to the attached figures. Furthermore, in the following description, a case will be described in which a vertical substrate processing apparatus (hereafter referred to simply as a “processing apparatus”) that performs diffusion processing, CVD processing, or the like on substrates is used as a substrate processing apparatus.

FIGS. 1 and 2 show one example of a processing apparatus equipped with an apparatus controller. FIG. 1 is a perspective view of the external appearance, and FIG. 2 is a side view of the processing apparatus shown in FIG. 1. Furthermore, these figures have been prepared using the see-through method.

In the processing apparatus 10 of the present embodiment, an I/O stage (holding jig receiving member) 105 which is used to insert pods (substrate accommodating vessels) 100 that accommodate wafers (substrates) made of silicon or the like into a housing 101 from the outside, and conversely to remove the pods from the interior of the housing 101 to the outside, is attached to the front surface of the housing 101, and cassette shelves (carrying means) 109 which are used to store inserted pods 100 are installed inside the housing 101. Furthermore, an N₂ purging chamber (air-tight chamber) 102 which is a wafer conveying area and which constitutes a loading and unloading space for boats (substrate holding means) 217 described later, is provided in the housing 101. This N₂ purging chamber 102 is a tightly sealed chamber; when processing is performed on the wafers, the N₂ purging chamber 102 is filled with an inert gas such as N₂ gas or the like in order to prevent the formation of natural oxidation films on the wafers.

Currently, a type referred to as FOUP is primarily used for the aforementioned pods 100. The wafers can be conveyed while being isolated from the atmosphere by closing an opening part formed in one side surface of each pod 100 by means of a cover (not shown in the figures), and wafers can be inserted into or removed from the inside of the pod 100 by removing the cover. For this purpose, a pod opener (opening and closing means) 108 which removes the cover of the pod 100 and provides communication between the atmosphere inside the pod 100 and the atmosphere inside the N₂ purging chamber 102 is installed on the front surface side of the N₂ purging chamber 102.

The conveying of the pods 100 between the pod opener 108, cassette shelves 109, and I/O stage 105 is accomplished by means of a cassette transfer mechanism 114. Air that has been cleaned by a cleaning unit (not shown in the figures) installed in the housing 101 is caused to flow into the conveying space for the pods 100 used by this cassette transfer mechanism 114.

The interior of the N₂ purging chamber 102 is provided with a boat 217 in which a plurality of wafers can be stacked in multiple tiers, a substrate positioning device 106 which aligns the positions of notches (or orientation flats) in the wafers with arbitrary positions, and a wafer transfer mechanism (conveying means) 112 which conveys wafers between the pod 100 on the pod opener 108, the substrate positioning device 106, and the boat 217. Furthermore, a processing chamber 202 which is used to process the wafers is installed above the N₂ purging chamber 102, and the boat 217 can be loaded into the processing chamber 202, or unloaded from the processing chamber 202, by a boat elevator (raising and lowering means) 115.

Next, the operation of the processing apparatus 10 of the present embodiment will be described.

First, the pod 100 that has been conveyed from the outside of the housing 101 by an AGV, OHT, or the like is placed on the I/O stage 105. The pod 100 that has been placed on the I/O stage 105 is conveyed directly onto the pod opener 108, or is conveyed onto the pod opener 108 after temporarily being stocked on the cassette shelves 109, by the cassette transfer mechanism 114. The cover of the pod 100 that has been conveyed onto the pod opener 108 is removed by the pod opener 108, and the atmosphere inside the pod 100 is caused to communicate with the atmosphere in the N₂ purging chamber 102.

Next, the wafer conveying mechanism 112 removes the wafers from the interior of the pod 100 in a state in which the interior of the pod 100 is in communication with the atmosphere in the N₂ purging chamber 102. The wafers thus removed are positioned by the substrate positioning device 106 so that notches are set in predetermined specified positions. Following this positioning, the wafers are conveyed to the boat 217.

When the conveying of the wafers to the boat 217 is completed, the furnace opening shutter 116 (FIG. 2) of the processing chamber 202 is opened, the boat elevator 115 is raised, and the boat 217 carrying the wafers is loaded into the processing chamber 202 by the raising of the boat 217. In a state in which this loading has been completed, the cover of the aforementioned boat 217 tightly closes the entry opening of the processing chamber 202.

Following the loading of the boat 217, i.e., the loading of the wafers, arbitrary processing is performed on the wafers in the processing chamber 202, and following this processing, the wafers and pod 100 are removed to the outside of the housing 101 by a procedure that is the opposite of that described above.

FIG. 3 is a block diagram of an apparatus controller 220 that is used to automate the aforementioned processing apparatus 10.

The apparatus controller 220 has an operating part 221 and a control part 222 as processing means. The operating part 221 has an operation controller 223 used to set, modify, and otherwise manipulate programs. The operation controller 223 is connected to the aforementioned control part 222 via an LAN so that communications are possible. Furthermore, a monitor (display means) described later is connected to the operation controller 223 as a user interface, and a key input means (described later) is provided.

The aforementioned control part 222 has a temperature controller which performs feedback control of the temperature of a heater thermocouple on the basis of the heating temperature of the aforementioned processing chamber 202, a pressure controller which performs feedback control of the pressure in the aforementioned processing chamber 202 on the basis of the detection temperature of a pressure sensor, a mass flow controller which performs feedback control of the flow rate of the raw-material gas on the basis of a flow rate sensor, a mechanism controller which controls various types of mechanisms on the basis of the detection value of a position sensor or rotational angle sensor, and a main controller which controls these sub-controllers and is connected to the operation controller 223 of the operating part 221, so that communications are possible.

Furthermore, the aforementioned mechanism of the processing apparatus 10 includes the substrate positioning device 106, the pod opener (opening and closing means) 108, the wafer transfer mechanism (conveying means) 112, the cassette transfer mechanism 114, the boat elevator 115, and the like, and the mechanism controller controls various actuators (driving parts) on the basis of the set value of the recipe (described later) and the detection values of sensors that sense the operations of these various actuators.

The aforementioned apparatus controller 220 has a fixed storage device such as a memory, hard disk 226, or the like, and a database is built in this fixed storage device. A plurality of recipes used for substrate processing is stored in this database. These recipes are programs which determine the temperature of the aforementioned processing apparatus 10 (temperature of the atmosphere inside the processing chamber 202, temperature of the exhaust pipe, and the like), pressure (pressure inside the processing chamber 202, pressure in the piping, and the like),and flow rate (flow rate of the raw-material gas into the processing chamber 202, flow rate of the carrier gas, flow rate of the substituent gas, and the like) on the basis of the processing conditions of the aforementioned processing apparatus 10, such as CVD, oxidation, annealing, diffusion, and the like, and which control various types of controllers installed in the aforementioned processing apparatus 10, such as the temperature controller, pressure controller, mass flow controller, mechanism controller, and the like.

The aforementioned plurality of recipes is prepared by an operator. When the operator prepares these recipes, a recipe preparation screen is called up from the aforementioned database and is displayed on the monitor screen.

FIG. 4 shows one example of this monitor screen 230. When the aforementioned apparatus controller 220 is started, the monitor screen 230 is called up from the aforementioned database by the aforementioned operating part 221, and is displayed on the monitor 227. An operating panel 231 and a character/numeral/symbol table 241 are displayed on the monitor screen 230. The operating panel 231 and character/numeral/symbol table 241 are disposed on the upper side and lower side of the monitor screen 230 so that the respective screens are framed.

For example, a “PM” button (processing module button) 232, a “system” button 233, an “edit” button 234, a “back” button 235, a “next” button 236, a “data log button” 237, a “set-up” button 238, and the like are displayed on the operating panel 231 as operating buttons used for screen call-up and editing.

When the aforementioned operating part 221 detects that [one of] the aforementioned operating buttons has been touched by the fingers or a pin, a program is started by each touch of one of the buttons, and the related screen is called up, or the screen is switched.

For example, when the aforementioned operating part 221 senses that the “PM” button 232 has been touched, the operating part 221 transmits the PM screen (not shown in the figures) stored in the aforementioned database to the monitor 227, and displays this screen on the monitor screen 230. When the operating part 221 senses that the “data log” button 237 has been touched, the operating part 221 transmits the data log screen (not shown in the figures) stored in the aforementioned database to the monitor 227, and displays this screen on the monitor screen 230, and when the operating part 221 senses that the “set-up” button 238 has been touched, the operating part 221 transmits the set-up screen 242 stored in the aforementioned database to the monitor screen 227, and displays this screen on the monitor screen 230.

Furthermore, when the operating part 221 senses that the “edit” button 234 has been touched, the operating part 221 allows editing of the various screens displayed on the monitor screen 230, and when the operating part 221 senses that the character/numeral/symbol table 241 has been touched, the operating part 221 starts the character input system, and allows input into the character/numeral/symbol table 241.

Furthermore, when the operating part 221 senses that the “save” button has been touched, the operating part 221 starts a save program, and saves the screen or file edited on the operating screen in the aforementioned database, and when the operating part 221 senses that the “ESC” button has been touched, the operating part 221 starts an escape program that returns to the original monitor screen 230.

Furthermore, when the operating part 221 senses that the “back” button 235 on the operating panel 231 has been touched after a plurality of screens has been called up on the monitor screen 230, the operating part 221 starts a program that displays the screens displayed on the monitor screen 230 each time that the button is touched in the opposite order from the order in which the screens were called up. Furthermore, when the operating part 221 senses that the “next” button 236 has been touched, the operating part 221 starts a program that displays the called-up screens in the order in which the screens were called up.

Furthermore, when the operating part 221 senses that a character or numeral displayed in the character/symbol table 241 used as a key input means has been touched with the fingers, a pen, or the like, the operating part 221 starts a program that inputs the touched character or numeral into a cell or box on the aforementioned screen.

Thus, when the operating part 221 senses that the “PM” button (processing module button) 232, “system” button 233, “data log” button 237, or “set-up” button 238 has been touched, the operating part 221 starts the program corresponding to the respective button, and calls up the related screen (an operating screen in each case) stored in the aforementioned database. When the operating part 221 senses that the “edit” button 234, “save” button 239, “ESC” button 240, “back” button 235, “next” button 236, or key of the character/numeral/symbol table 241 has been touched, the operating part 221 starts the program corresponding to the respective button or key.

The buttons and keys described below refer to program buttons or program keys in the software that execute corresponding programs when the touching of the buttons or keys is thus sensed by the operating part 221.

When the operator prepares a recipe, the operator performs the following steps in the order indicated: a call-up step in which the operator presses the “PM” button (processing module button) 232 and calls up the PM screen (not shown in the figures), a step in which the recipe preparation screen required for substrate processing is called up from the aforementioned database using selection keys (not shown in the figures) provided on this PM screen, a step in which a recipe is prepared using this recipe preparation screen (not shown in the figures) as an operating screen, and a step in which the recipe is saved in the aforementioned database.

When the operator uses the recipe preparation screen to input commands and parameters into the cells or boxes displayed on this recipe preparation screen, and uses the selection boxes to select items or commands displayed in the selection boxes, the operating part 221 confirms the designation of commands and setting of parameters for the sequences of the various controllers described above, and confirms the setting contents of the recipe corresponding to processing conditions such as the temperature inside the furnace of the aforementioned processing apparatus 10, the pressure inside the furnace, the raw-material gas flow rate, the processing time, and the like.

The aforementioned character/numeral/symbol table 241 is used for the input of commands and parameters.

After the recipe has been prepared, the “save” button 239 is touched, the edited contents of the recipe confirmed by input and selection is reflected in the recipe (recipe file) in the database, and an image file of the recipe preparation screen is saved in the database. When an image file of the recipe preparation screen is saved in the database, this can be used later for analysis, and analysis operations are facilitated.

Here, in the present embodiment, when a recipe is prepared, the operations include an operation in which the recipe preparation screen is called up and the recipe settings are confirmed, and an operation in which changes are made according to the apparatus structure of the aforementioned processing apparatus 10 and processing conditions such as the film type and the like. Furthermore, in cases in which the operating part 221 changes the recipe settings, the system is programmed so that the recipe prior to change (recipe file) is saved in the database as a back-up file. When a back-up file of the recipe is saved in the database, post-analysis reference tasks and the operation of restoring the file to the original settings are subsequently facilitated and trouble caused by changes can quickly be dealt with. When the “ESC” button 240 is touched after the recipe has been prepared and saved by means of the “save” button 239, the screen is switched to the original monitor screen 230.

In the present embodiment, when the aforementioned processing apparatus 10 is brought up and an adjustment operation is performed, the “set-up” button 238 is touched. When the “set-up” button 238 is touched, the aforementioned operating part 221 calls up the set-up screen 242 shown in FIG. 4 from the aforementioned database, and this screen is displayed on the monitor screen 230. The set-up screen 242 displays a cell 243 used to input the name of the “operator,” a scroll box 244 as a selection box for selecting the “film type,” an “L/L chamber mechanism” (loading and locking chamber mechanism) scroll box 245 as a selection box for selecting the apparatus mechanism, and radio buttons 246 and 247 used to switch between “before editing” and “after editing.”

When “Si₃N₄” is selected by the scrolling button 244a of the scroll box 244 used to select the “film type,” and “no L/L chamber mechanism” is selected by the scrolling button 245a of the scroll box 245 used to select the presence or absence of the L/L chamber mechanism, the operating part 221 starts a search program with the substrate processing set as CVD processing, the film type set as Si₃N₄ (silicon nitride), and the atmosphere conditions set as a reduced-pressure or normal-pressure atmosphere with no “L/L chamber mechanism.” Then, the aforementioned database is searched with the search conditions of the search program set as “Si₃N₄” and “no L/L chamber mechanism,” and search data that matches the search conditions is displayed on the set-up screen 242. Furthermore, the L/L chamber mechanism is an abbreviation for a load-and-lock chamber mechanism which prevents the formation of an oxidation film on the substrates by maintaining the interior of the processing apparatus 10 at a high-vacuum atmosphere.

In this case, “search data” refers to data of all of the operating items required to perform the adjustment operations involving the aforementioned processing apparatus 10, and data indicating the degree of progression associated individually with the operating items.

After acquiring the search data, the operating part 221 displays this data on the set-up screen 242. In the case of the data of the operating items, since the respective sets of data follow an operating sequence in the adjustment operations, the operating part 221 lines the data up in this order, and displays the data on the monitor screen 230. In the search results, the data of the operating items constitutes “switching on of the power supply,” “parameter confirmation,” “MFC flow rate check,” “pressure leak check,” “heater power switch,” “blank firing of the heater,” “heater power check,” “blank firing of the heater,” “teaching,” “interlock,” “quartz part assembly,” “vacuum test,” “blank firing of quartz,” “temperature setting,” “sequence test,” “He leak test,” “tape/jacket heater attachment confirmation,” “formation gas discharge,” and “processing test.” The operating part 221 lines the data of these operating items up in two rows in the operating sequence, and displays the data on the monitor screen 230 using characters that can be visually recognized. Furthermore, operating numbers used to indicate the operating sequence of the operating items in the adjustment operations are displayed on the left side of each operating item. The display format of the aforementioned operating items is not limited to the format described above. All of the operating items may be displayed at one time on the same screen as in the present embodiment, or only a few items currently being handled among all of the operating items may be displayed.

Here, in the aforementioned adjustment operations, the “power supply check” refers to an operation for checking whether or not the power supply can be switched on for the mechanism of the aforementioned processing apparatus 10 in the order determined by the recipe, i.e., respective actuators (driving parts) of the substrate positioning device 106, the pod opener (opening and closing means) 108, the wafer transfer means (conveying means) 112, the cassette transfer means 114, the boat elevator (raising and lowering means) 115, and the like, and the heater used to elevate the temperature inside the processing chamber 202. In cases in which this operation is performed, reference is made to a recipe relating to the switching on of the power supply on the aforementioned operating screen.

The “MFC flow rate check” refers to a checking operation in which it is checked whether or not the MFC (mass flow controller) is operating correctly, and whether or not the flow rates of the raw-material gas, carrier gas, and substituent gas (slm) determined in the respective recipes can be achieved by the MFC. In the checking operation, reference is made to a recipe that stipulates the MFC flow rate, and an alarm condition table.

The “parameter confirmation” refers to an operation for confirming parameters such as “configuration parameters,” “function parameters,” and the like. In this operation, reference is made to configuration parameters, function parameters, and the like in order to confirm apparatus control constants such as the number of MFC, the number of valves, the number of temperature control zones, the presence or absence of pressure control, and the like.

The “pressure leak check” refers to an operation in which a leak pressure is applied separately to the raw-material gas supply system, substituent gas supply system, and exhaust system (corresponding to the gas piping shown in FIG. 3) of a processing apparatus (processing furnace) 99, and a check is made as to whether or not leaks actually occur. In this operation, reference is made to recipes that determine the pressures of the respective systems, and to a leak check table.

Furthermore, the “blank firing of the heater” refers to an operation in which blank firing of the surface of the heater is performed by passing current through the heater so that heat is generated. For the temperature of the blank firing, reference is made to a recipe that stipulates heater control.

The “heater power switch” is an operation for testing whether or not the on/off switching of the heater is possible. In this operation, reference is made to a recipe that stipulates the control of the heater.

“Teaching” refers to an operation in which the set values of the aforementioned mechanism controllers are adjusted and the aforementioned sensors are attached by setting the traveling range and delivery position of the boat 217 of the aforementioned wafer transfer mechanism (conveying means), the removal position for the cover of the pod in the pod opener (opening and closing means) 108, the transfer and conveying positions of the aforementioned cassette transfer means 114, and the like on the basis of a two-dimensional or three-dimensional recipe. In this operation, reference is made to position parameters that are used to control the aforementioned mechanisms.

Furthermore, “interlock” refers to a checking operation for checking whether or not interlocks such as a hard interlock, soft interlock (processing system, conveying system), or the like are operating, and whether or not set interlocks are operating under interlock conditions. In this operation, reference is made to a recipe that is used to control interlock, and to an alarm condition table.

“Assembly of quartz parts” refers to an operation for “performing mainly the installation of the reaction tube inside the apparatus.” There is no recipe to which reference is made in this operation; in this case, the operating part 221 displays the characters “no recipe” as the corresponding recipe information on the monitor screen 230.

“Vacuum test” refers to a test operation that is performed in order to check whether or not the vacuum pump is operating normally as a pressure reduction exhaust means used to evacuate the atmosphere from the inside of the processing chamber 202 and place this chamber in a reduced-pressure atmosphere, and in order to check whether or not the interior of the processing chamber 202 can be adjusted to a specified reduced-pressure atmosphere by the vacuum pump. In this operation, reference is made to a recipe that is used to set the pressure by means of the vacuum pump.

“Blank firing of quartz” refers to an operation in which blank firing of the processing chamber (reaction tube) and the aforementioned boat 217 is performed, and an operation is performed in order to prevent the admixture of impurities in the substrate processing. In this operation, reference is made to a recipe that is used to heat the heater.

“Temperature setting” refers to an operation that relates to the setting of the temperature of the heater for raising the temperature of the atmosphere inside the aforementioned processing chamber 202. In this temperature setting, reference is made to a recipe that is used to control the temperature of the heater, and to a temperature correction table.

The “sequence test” refers to an operation for checking whether or not the aforementioned mechanisms are operating according to the proper sequence. In this operation, reference is made to a position table used to control the mechanisms, a speed table, conveying system configuration parameters, and conveying system function parameters as recipes.

The “He leak test” refers to an operation for checking the pressure resistance in order to determine whether or not He can be supplied to the interior of the aforementioned processing apparatus 10, and whether or not He leakage occurs within a specified leak pressure. In this operation, reference is made to a recipe relating to leakage.

The “tape/jacket heater attachment confirmation” refers to an operation for confirming whether or not the tape used for heat insulation/temperature maintenance or jacket-form heater can be attached in a specified position of the exhaust pipe or the like. In this operation, there is no recipe to which reference is made; in this case, the operating part 221 displays the characters “no recipe” on the monitor screen 230 as the corresponding recipe information.

“Formation gas discharge” refers to an operation for checking whether or not the formation gas can be supplied to the processing chamber (reaction furnace) and whether film formation is possible on the substrate. In this operation, reference is made to a recipe that stipulates the flow rate of the raw-material gas, the pressure, and the opening and closing time of the opening and closing valve.

Finally, “processing test” refers to an operation for testing whether or not the aforementioned processing is performed in a stage in which all of the aforementioned checks and confirmations have been completed, and the respective parts of the aforementioned processing apparatus 10 are operating normally, and whether or not films of a specified thickness can be formed in a normal manner on the surfaces of the silicon substrates subjected to substrate processing. In this operation, reference is made to a recipe used for film formation, inspection, and the like.

In the example shown in FIG. 4, the set-up screen 242 displays in a visibly distinguishable form the data of all of the operating items required to perform an adjustment operation involving the processing apparatus 10 in a case in which the film type is Si₃N₄ (silicon nitride) and there is no L/L chamber mechanism, i.e., in a case in which Si₃N₄ film formation processing is performed in a reduced-pressure atmosphere at a low degree of vacuum.

In this case, the processing conditions are different when a different film type is selected based on the film type; accordingly, the corresponding operating items are found from the database and are displayed on the set-up screen 242.

Similarly, the processing conditions are different even in cases in which no “L/L chamber mechanism” is selected; accordingly, the corresponding operating items are found from the database and are displayed on the set-up screen 242.

Furthermore, in the set-up screen 242 shown in FIG. 4, the set-up items are missing at an intermediate point; this is done in order to display the required operating items in the blank areas in cases in which the processing conditions and apparatus structure are changed. Furthermore, the system is devised so that a selection can be made not only in terms of film type and apparatus structure, but also in terms of pressure. For example, reduced pressure or atmospheric pressure can be selected. Moreover, the system may also be devised so that the presence or absence of plasma can be selected. As another example of the apparatus structure, the system may also be devised so that the presence or absence of plasma electrodes can be selected.

Furthermore, recipe name display cells 248, check boxes 249 used as input boxes, arrow displays 250 used to indicate the completion of operations, and date and time display cells 251 are displayed on the set-up screen 242. In this case, the check boxes 249 are displayed on the left side of each operating item, and the recipe name display cells 248 and the date and time display cells 251 are displayed adjacent to each other directly beneath the respective operating items. Moreover, the arrow displays 250 are displayed on the opposite side of the check boxes 249 from the respective operating items. Furthermore, in the present embodiment, only a single operator entry cell 243 is shown on the set-up screen 242; however, it would also be possible to provide cells so that the operator can be entered for each operating item.

Furthermore, cells may also be provided so that the conditions of progress can be entered for each operating item.

In addition, the system may be devised so that when the recipe performed for each operating item is completed, a check mark is automatically entered in the check box 249 of the set-up screen 242 corresponding to the operating item for which the recipe was performed, thus indicating that the operations have been completed.

Operating items such as “switching on of the power supply,” “parameter confirmation,” and the like displayed on the aforementioned set-up screen 242 each have a button for calling up a manual relating to this operating item. When the button for one of the operating items is touched, the operating part 221 calls up the operator manual listing screen 252 shown in FIG. 5 from the aforementioned database. The system is programmed so that when the corresponding manual is selected from the plurality of apparatus set-up manuals displayed on this operator manual listing screen 252, this manual is displayed on the monitor screen 230.

FIG. 5 shows the operator manual listing screen 252. In this figure, apparatus set-up manuals are displayed in order as respective operator manuals on the operator manual listing screen 252, and a number is appended to the end of each apparatus set-up manual. The numbers at the ends of each of the apparatus set-up manuals agree with the operating numbers assigned to the operating items displayed on the aforementioned set-up screen 242.

When one of the aforementioned operating item buttons, e.g., the “pressure leak check” button, is touched and the operator manual listing screen 252 is displayed, the operator touches the apparatus set-up manual of number “4,” which is the same as the operating number “4” next to the “pressure leak check” button. Consequently, the contents of the apparatus set-up manual corresponding to “pressure leak check” are displayed on the monitor screen 230. Similarly, in a case in which the “switching on of the power supply” button is touched, and the operator manual listing screen 252 is displayed, the operator touches the apparatus set-up manual of number “1,” which is the same as the operating number “1” at the side of the “pressure leak check” button. Consequently, the contents of the apparatus set-up manual corresponding to the switching on of the power supply are displayed on the monitor screen 230. Furthermore, in this case, it would also be possible to devise the system so that when the buttons for the respective operating items are touched, the manual corresponding to the touched operating item is directly displayed without displaying the operator manual listing screen 252.

Thus, when an apparatus set-up manual is called up and displayed as the operator manual screen, the apparatus set-up manual having the same number as the operating number of the operating item is selected. Furthermore, in cases in which the apparatus set-up manuals is too big to be displayed on the aforementioned apparatus set-up listing screen, a screen structure that allows scrolling of the screen is used, and a search is made within the apparatus set-up manual by using a scroll button (not shown in the figures).

To exit the operator manual listing screen 252, the OK button for the same screen is touched. When this button is touched, the operating part 221 switches the screen to the set-up screen 242. In the present embodiment, the operating number and the manual number are caused to match. However, the present invention is not particularly limited to this option; the system may be devised so that there is an operator manual listing screen for each operating item. For example, in the case of “switching on of the power supply,” the system may be devised so that only a single file is displayed on the manual screen, and in the case of “parameter confirmation,” the system may be devised so that ten files are displayed.

Basically, the operating contents and operating procedure are described for each operating item in the respective apparatus set-up manuals. Furthermore, if necessary, in addition to recipe information required for the search and processing of the operating part 221, such as recipe names, recipe numbers, and the like to which reference is made in the operations, it is also possible to provide entries related to supplementary items such as descriptions, contents, and the like relating to recipes, as well as operating procedures, necessary check items, necessary maintenance parts and control destinations, inquiry destinations, and the like. When reference is made to these set-up manuals, standardization of the operations can be achieved and adjustment operations can be performed without requiring training.

For example, in the case of the MFC flow rate check, an adjustment manual for the MFC flow rate check is displayed. This adjustment manual is prepared using an Excel CSV file, and this CSV file is displayed without any modifications on the screen.

Furthermore, in these apparatus set-up manuals, a file structure is used which allows scrolling of the screen by means of a scrolling button or a scroll bar (not shown in the figures); however, it would also be possible to use a file structure in which the screens are switched in page units by using the “next” button 235 or “back” button 236 of the aforementioned operating panel 231.

Thus, the apparatus set-up manuals differ in the contents of the operating items; accordingly, a search function (search screen) may be provided for each apparatus set-up manual in order to search the entire manual for key words. Furthermore, in this embodiment, the apparatus set-up manuals are files with a format corresponding to an Excel import function so that text files can be edited in a CSV format using Excel (trademark of Microsoft Co.). However, it would also be possible to use files in an HTML or XML format that display figures, symbols, or images simultaneously with the text file in order to facilitate understanding.

To exit the screen displaying the apparatus set-up manual, the “ESC” button of the aforementioned operating panel 231 is touched.

Thus, the set-up screen 242 of the present embodiment is simple to operate and can also display apparatus set-up manuals; accordingly, the operator can grasp all of the operating contents of the respective operating items inside the clean room without carrying clean notes and associated technical materials into the clean room.

FIG. 6 is a block diagram showing screen processing performed by the operating part 221 in order to inform the operator of the conditions of progress of the operating items.

When one of the aforementioned check boxes 249 is switched on (see FIG. 5), the aforementioned operating part 221 captures the current instant in time from the aforementioned control computer, and displays this as the time of completion of operation, as well as the year, month, and day of the completion of operation, in the date and time display cell 251 (display of the current time by checking the check box). Next, the aforementioned operating part 221 acquires the recipe name or the recipe preparation screen name from the recipe or the recipe preparation screen selected by the “PM” button 232 and the selection button of the aforementioned recipe preparation screen, and inputs and displays the acquired recipe name or recipe preparation screen name in the recipe name display cell 248 of the set-up screen 242. The recipe name and the operator name can be input and entered by the operator (display of the recipe and operator manual settings).

Then, when the operator item is touched on the monitor screen 230, the operating part 221 opens the CSV file of the apparatus set-up manual (CSV file is OPEN), displays the operator manual, and performs processing that displays the aforementioned operator manual listing screen 252 on the monitor screen 230 (operating screen) (display of the operator manual screen by touching a button or key).

In this case, the operating procedure which is one of the contents of the apparatus set-up manual may be prepared separately and stored in the database as a procedure that corresponds to the film type or apparatus structure, or may be set as a data file that describes the operating procedure corresponding to differences in the film type or apparatus structure for the apparatus set-up manual for the same operating item.

Next, one example of an adjustment operation involving the aforementioned processing apparatus 10 will be described using the aforementioned set-up screen 242 with reference to FIGS. 5 and 7.

In a case in which the film type is Si₃N₄ (silicon nitride) and there is no L/L chamber mechanism, i.e., in a case in which Si₃N₄ film formation processing is performed in a reduced-pressure atmosphere having a low degree of vacuum, the data of all of the operating items for the processing apparatus 10 is displayed on the set-up screen 242. In performing the adjustment operation involving the processing apparatus 10, for example, the “pressure leak check” button is touched, the operator manual listing screen 252 is displayed on the monitor screen 230, the apparatus set-up manual having the same number as the number “4” assigned to the arrow display 250 displayed beside the “pressure leak check” button is touched, and an adjustment operation relating to the pressure leak check is performed while referring to these contents on the monitor screen 230.

When an adjustment operation relating to the pressure leak check is completed, a check is made in the check box beside “pressure leak check” on the set-up screen 242, and this check mark is displayed as shown in FIG. 7. When the operating part 221 senses that the check mark has been made, the operating part 221 starts the program associated with this check box, and inputs and displays the recipe name or recipe preparation screen name associated with the pressure leak check in the aforementioned recipe name display cell 248. At the same time, the operating part 221 inputs and displays the current time as well as the year, month, and day in the date and time display cell 251. In this case, the time as well as the year, month, and day displayed in the date and time display cell 251 are simple numerals and do not have a function that counts up.

Furthermore, the time as well as the year, month, and day displayed in the date and time display cell 251 are acquired from the clock of the control computer, and the control computer maintains precision by acquiring the time as well as the year, month, and day from a standard time, e.g., Internet standard time. In the present embodiment, only one cell in which the operator name is entered is displayed on the set-up screen 242; however, it is desirable to provide cells for entering not only the recipe name, but also the name of the operator, for each operating item. If this is done, it can easily be understood who has performed the respective operating items, and it can immediately be determined later who requires confirmation in cases in which trouble or the like occurs.

Furthermore, when the aforementioned check box 249 is touched and a check mark is entered in this check box 249, the operating part 221 changes the color of the arrow display 250 beside the operating item, in this case the pressure leak check, to a color that can be distinguished from the color of the other arrow displays (operating items that have not been started) 250, e.g., from “blue” to “yellow,” as indicated by the hatching in FIG. 7.

Thus, the recipe name or recipe preparation screen name is displayed in the recipe name display cell 248, the current time as well as the year, month, and day are displayed in the date and time display cell 251, and the color of the arrow display 250 is switched from “blue” to “yellow”; accordingly, the orientation of the arrow symbol indicates to the operator that the next operating item “heater power check” is the next operating item that is to be started.

Furthermore, if, as in the present embodiment, there are a total of three displays of the degree of progress that are used to inform the operator of the degree of progress of the operations when a check mark is input into the aforementioned check box 249, i.e., the recipe name display cell 248, arrow display 250, and date and time display cell 251, the operator can be informed of the degree of progress of the operations even in cases in which there is trouble in one of the displays of the degree of progress.

Furthermore, since the arrow displays 250, which constitute one of the displays of the degree of progress, transmit the degree of progress to the operator in visual terms, the conditions of progress are easy to understand. Accordingly, efficient adjustment operations can be performed while operations are handed off among a plurality of operators.

Thus, when an adjustment operation involving the processing apparatus 10 is performed using the set-up screen 242 of the present embodiment, even in cases in which the operation is handed off among a plurality of operators, the completed operating items and the names of the operators can be grasped while an operation involving each operating item is performed; accordingly, the operation can be carried out efficiently in a short time.

Furthermore, in cases in which an adjustment operation is carried over to a later date, the system is programmed so that when the “save” button 239 of the operating panel 231 is touched, the operating part 221 saves the set-up screen 242 in the aforementioned database in a state in which the screen image is saved, and when the “set-up” button 238 is touched at a later date, this set-up screen 242 is displayed on the monitor screen 230. Accordingly, there is no need for cumbersome operations such as carrying in of clean notes, confirming the operating contents by asking other persons, or the like, as there is in conventional techniques.

Furthermore, it is desirable that cells be provided so that memos can be entered for each operating item; in this case, the conditions maintained during an operation can be transmitted to other operators.

In addition, the system may also be devised so that when the aforementioned “save” button 239 is touched, the aforementioned set-up screen 242 is saved in a concentrated control device 20 described later, and is displayed on the monitor screen of the concentrated control device 20 at a later date.

In cases in which an adjustment operation is handed over to a later responsible party, the name of the operator is input into the operator entry cell 243 before the “save” button 239 is touched. This input is performed by the operator touching the “edit” button 234, starting the character input system, and using the character/numeral/symbol table 241.

Furthermore, in the aforementioned embodiment, a description was given in which the arrow displays 250 were used as displays of the degree of progress of the operations. However, if the color of the display of the degree of progress of the operations is thus switched, the operator can be effectively informed of the degree of progress of the operations; accordingly, a display that uses characters, figures, symbols, or a combination of these may be used instead of the arrow displays 250.

Furthermore, in the embodiment, a description was given in which when a check mark was entered by the operator in the check box 249 in the current time processing, the current time as well as the year, month, and day were displayed in the date and time display cell 251, and this time as well as the year, month, and day were taken as the time as well as the year, month, and day of the completion of operations involving each operating item. However, it would also be possible to devise the system so that the time as well as the year, month, and day are initially displayed in the time and date display cell 251 as a clock display, and when a check mark is entered in the check box 249, the clock is stopped, and this time as well as the year, month, and day are confirmed as the completion time of the operations involving the operating item in question.

Furthermore, it would also be possible to devise the system so that in cases in which a recipe is performed in the operating item, a check is automatically entered in the check box 249 when the recipe is completed, and the time at which this recipe is completed is confirmed as the time of completion of the operations.

Moreover, in the aforementioned embodiment, a total of three displays of the degree of progress were displayed in order to display the degree of progress of the operations. However, in cases in which the degree of progress of the operations is displayed, although any one of these displays may be used, the arrow displays 250 are desirable in visual terms. Furthermore, the system was devised so that the display of the degree of progress was displayed at the time of completion of operation for each operating item. However, it would also be possible to devise the system so that when a recipe or recipe preparation screen is displayed, the recipe name or recipe preparation screen is displayed in the recipe name display cell 248, and the degree of progress is displayed during the operations by taking this display as a display of the degree of progress or devising other measures.

Furthermore, the system may also be devised so that a checking screen for checking an operation that has not yet been begun, or the completion of an operation, is provided for each operating item. If this is done, an operation that has not yet been started, or the completion of an operation, can be confirmed for the operating contents of each operating item by means of the checking screen; accordingly, confirmation in cases in which such operations are handed off or carried over is facilitated.

Furthermore, by changing the color of the arrow displays 250 constituting one of the displays of the degree of progress, the system was devised so that an operation that had not yet been started and an operation that was completed could be distinguished; however, it would also be possible to provide displays of an operation that has not yet started or an operation that has been completed for each operating item.

FIG. 8 shows a semiconductor manufacturing system for controlling a semiconductor manufacturing apparatus.

The semiconductor manufacturing system is constructed from a plurality of semiconductor manufacturing apparatuses (processing apparatuses) 10, a concentrated control device 20, and a network 30 that connects the plurality of semiconductor manufacturing apparatuses 10 to the concentrated control device 20.

The concentrated control device 20 stores recipes used by the respective semiconductor manufacturing apparatuses 10, and performs control such as editing the respective recipes, storing the history of the recipes used, and the like. The concentrated control device 20 transfers the recipes that are to be performed to the respective semiconductor manufacturing apparatuses 10 via the network 30. Furthermore, the concentrated control device 20 has the function of recording data for the respective semiconductor manufacturing apparatuses 10, and collects various data for the respective semiconductor manufacturing apparatuses 10 via the network 30.

FIG. 9 shows the structure of the concentrated control device 20 in the present embodiment.

The concentrated control device is constructed from an internal storage part (hereafter referred to as an internal memory) 21 used as a first storage part, an inter-device communications part 22 used as a detection part, an input-output part 23, an external storage part 27 used as a second storage part, and a display control part 28. The control part is constructed so that a database is read from the aforementioned internal memory 21 and external storage part 27, a plurality of operating items relating to adjustment operations involving the respective semiconductor manufacturing apparatuses is displayed in order, and when the aforementioned adjustment operations is performed, the recipes used in the aforementioned respective operating items are displayed on the monitor screen. This control part (except for the storage parts) and the inter-device communications part 22 are constructed from a CPU 24 which realizes various functions by means of programs.

The internal memory 21 stores various data and the like detected from the respective semiconductor manufacturing apparatuses. The internal memory 21 is constructed using a RAM or the like.

The inter-device communications part 22 connects to the network 30, detects at specified time intervals various data from the respective semiconductor manufacturing apparatus 10 sent via the network 30, and stores this data in the internal memory 21.

The input-output part 23 has a keyboard or mouse (keyboard or the like) 23a that constitutes an input means, and a display device 23b that constitutes an output means. A plurality of substrate processing apparatuses is selected from the keyboard or the like 23a while viewing the display screen (described later) displayed by the display device 23b, display requests are made to the display control part 28, and the set-up screen 242 is displayed on the display device 23b.

The external storage part 27 receives save commands from the display control part 28 or processing apparatuses 10, and saves data. For example, a hard disk (HD) can be used as the external storage part 27. Below, the external storage part will be referred to as a hard disk (HD) 27.

When there are various screen display requests from the keyboard or the like 23a of the input-output part 23, the display control part 28 reads out the database from the hard disk (HD) 27, and sends display commands to the display device 23b.

A monitor is connected as a display means to the aforementioned concentrated control device 20, and the set-up screen 242 for the processing apparatuses 10 shown in FIG. 4 is displayed on the screen of the monitor of the concentrated control device 20 via the network 30.

In this case, the concentrated control device 20 is constructed so as to display a selection screen (not shown in the figures) for monitoring the set-up operations; for example, a set-up screen 242 for one or a plurality of semiconductor manufacturing apparatuses 10, which are selected from the plurality of semiconductor manufacturing apparatuses 10 displayed on the selection screen, is displayed on the monitor of the concentrated control device 20. Accordingly, the conditions of progress of the adjustment operations can also be grasped for each semiconductor manufacturing apparatus 10 on the monitor located on the side of the concentrated control device 20, and adjustment operations can be carried out while checking on the conditions of progress of the set-up operations for a plurality of semiconductor manufacturing apparatuses 10 to ensure high efficiency.

Furthermore, in order to improve the control function of the concentrated control device, the system may also be devised so that a set-up screen 242 for all of the semiconductor manufacturing apparatuses 10 is displayed as a multi-screen on the monitor of the concentrated control device, and the set-up screen 242 for the semiconductor manufacturing apparatus 10 selected from the multi-screen is displayed in a single display that fills the monitor screen of the concentrated control device 20.

The processing apparatus 10 and concentrated control device 20 of the present embodiment, and the semiconductor manufacturing system constructed from this processing apparatus 10 and concentrated control device 20, may be summarized as follows:

(1) A first aspect of the substrate processing apparatus is a substrate processing apparatus in which substrates are processed by an operator who prepares recipes on an operating screen displayed on a display means, and a processing means that performs the prepared recipes, wherein a plurality of operating items relating to an adjustment operation involving the aforementioned substrate processing apparatus is displayed in order, and the recipes used in the aforementioned operating items during the aforementioned adjustment operations are displayed on the aforementioned operating screen. When a plurality of operating items relating to the adjustment operation involving the substrate processing apparatus is displayed in order on an operating screen in cases in which an adjustment operation involving the substrate processing apparatus is carried out, the operator can grasp the order of the plurality of operating items displayed on the operating screen to enhance the efficiency of the adjustment operation. Furthermore, in the case of operating items for which no adjustment operation is performed, the recipe used is not displayed on the operating screen, and in the case of operating items for which an adjustment operation has been completed, a display is performed, allowing the operation to be handed off smoothly.

(2) A second aspect of the substrate processing apparatus is a substrate processing apparatus in which substrates are processed by an operator who prepares recipes on an operating screen displayed on a display means, and a processing means that performs the prepared recipes, wherein the apparatus is constructed so that a plurality of operating items relating to an adjustment operation involving the aforementioned substrate processing apparatus is displayed in order, and the operating items displayed on the aforementioned operating screen differ according to the film type or apparatus structure. Thus, in this second aspect, operating items of an adjustment operation that corresponds to the film type or apparatus structure are displayed in order, allowing high reliability to be obtained.

(3) A third aspect of the substrate processing apparatus is a substrate processing apparatus in which substrates are processed by an operator who prepares recipes on an operating screen displayed on a display means, and a processing means that performs the prepared recipes, wherein the apparatus is constructed so that a plurality of operating items relating to an adjustment operation involving the aforementioned substrate processing apparatus is displayed in order, the aforementioned operating items form buttons, and when an input is made from the respective operating item buttons on the aforementioned operating screen, a manual corresponding to this operating item is displayed. In this third aspect, the operating items form buttons, and when an input is made from the respective operating item buttons on the aforementioned operating screen, a manual corresponding to this operating item is displayed. Accordingly, operations are carried out while making reference to manuals corresponding to the operating items, so that an adjustment operation which is accurate and efficient can be performed.

(4) A first aspect of the semiconductor substrate system is a substrate processing system constructed from a substrate processing apparatus that processes substrates, and a concentrated control device that is connected to at least one substrate processing apparatus, wherein the system is constructed so that a plurality of operating items relating to an adjustment operation involving the aforementioned substrate processing apparatus is displayed in order on the operating screen of the concentrated control device, and the recipes used in the aforementioned operating items during the aforementioned adjustment operations are displayed on the operating screen of the concentrated control device. If this structure is used, the order of a plurality of operating items relating to the adjustment operation involving the substrate processing apparatus can also be grasped at a glance on the operating screen of the concentrated control device. In the substrate system of this first aspect, the order of a plurality of operating items relating to the adjustment operation involving the aforementioned substrate processing apparatus can be grasped on the operating screen of the concentrated control device, and the recipes used in the aforementioned respective operating items during the adjustment operations can also be grasped; accordingly, accurate instructions can be given to the operator who performs the adjustment operation that involves the respective substrate processing apparatuses.

(5) A second aspect of the semiconductor substrate system is a substrate processing system constructed from a substrate processing apparatus that processes substrates, and a concentrated control device that is connected to at least one substrate processing apparatus, wherein the system is constructed so that a plurality of operating items relating to an adjustment operation involving the aforementioned substrate processing apparatus is displayed in order on the operating screen of the concentrated control device, and the operating items displayed on the operating screen of the aforementioned concentrated control device differ according to the film type or apparatus structure.

If this is done, operating items and the order of operating items relating to the adjustment operations corresponding to the film type or apparatus structure can be grasped for each substrate processing apparatus on the operating screen of the concentrated control device, so that accurate instructions can be given to the operator who performs the adjustment operation that involves the respective substrate processing apparatuses.

Furthermore, the semiconductor manufacturing apparatus 10 of the present invention can be used not only in semiconductor manufacturing apparatuses, but also in apparatuses that process glass substrates of the type used in LCD devices. Moreover, the present invention is not limited to a vertical processing apparatus, but can also be used in horizontal or single-wafer processing apparatuses. In other words, the present invention can be used in any apparatus that performs processing of substrates (semiconductor substrates, glass substrates, or the like) by preparing recipes or the like as a result of an operator making inputs using some kind of input means (keyboard, touch buttons or touch keys on an operating screen, or the like). Furthermore, for example, the present invention can also be used for oxidation, annealing, diffusion, or the like without a direct relationship to processing inside a furnace.

Thus, various modifications are possible in the present invention, and the present invention naturally extends to these modified inventions.

### BRIEF DESCRIPTION OF THE DRAWINGS

FIG. 1 is an external perspective view showing one example of a processing apparatus that has the apparatus controller of one embodiment of the present invention;

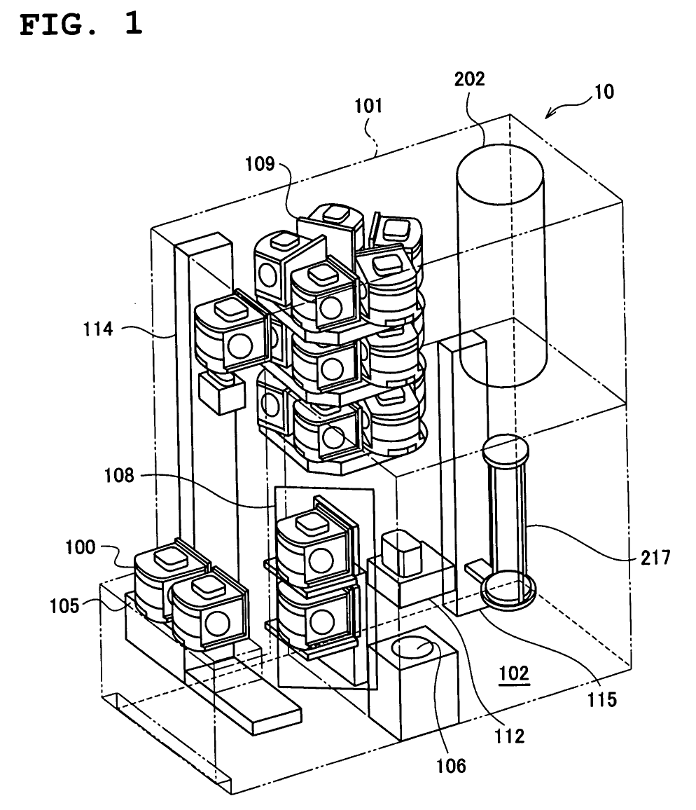

FIG. 2 is a side view of FIG. 1;

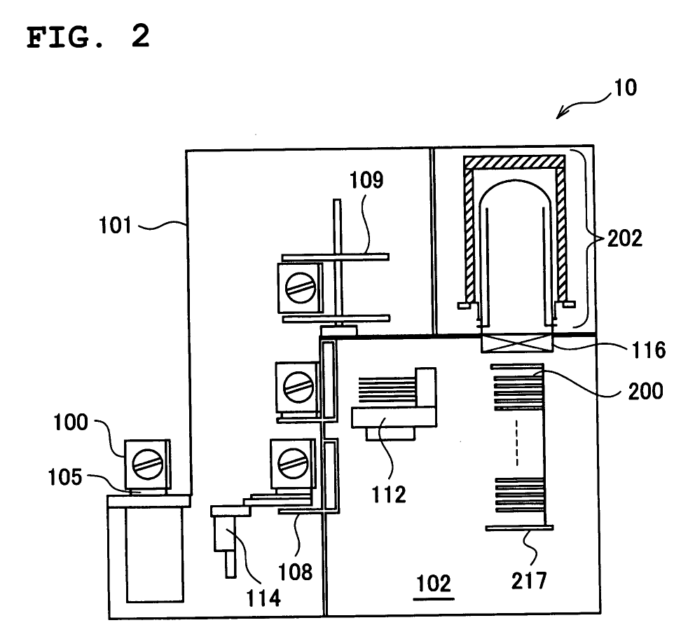

FIG. 3 is a block diagram of the apparatus controller used to automate the substrate processing apparatuses in one embodiment of the present invention;

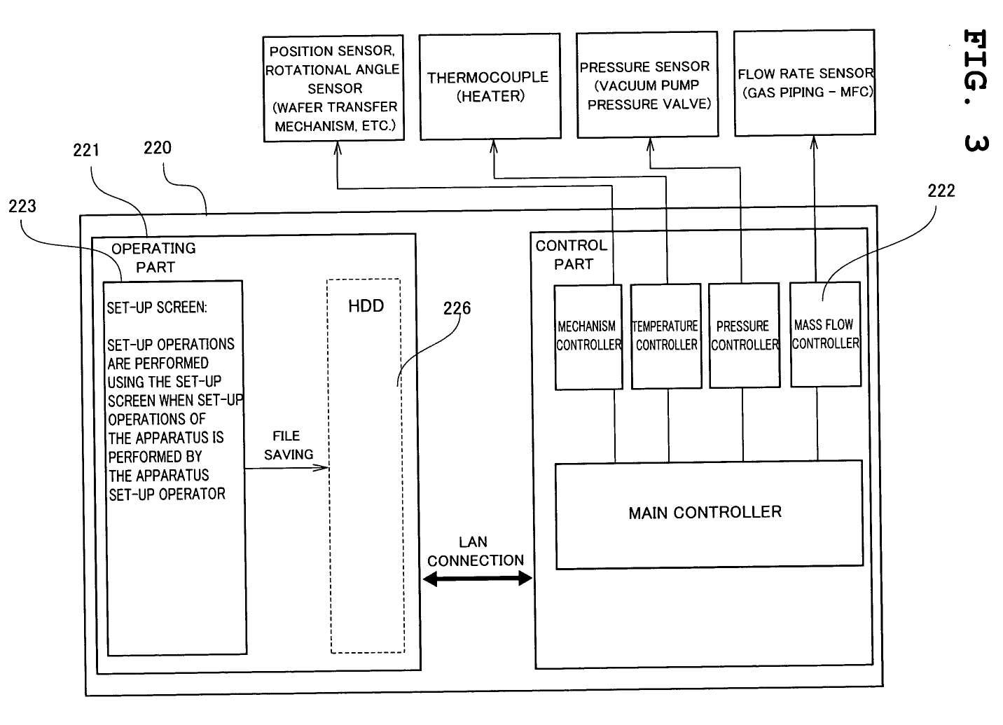

FIG. 4 is an explanatory diagram showing one example of the monitor screen showing the set-up screen in one embodiment of the present invention;

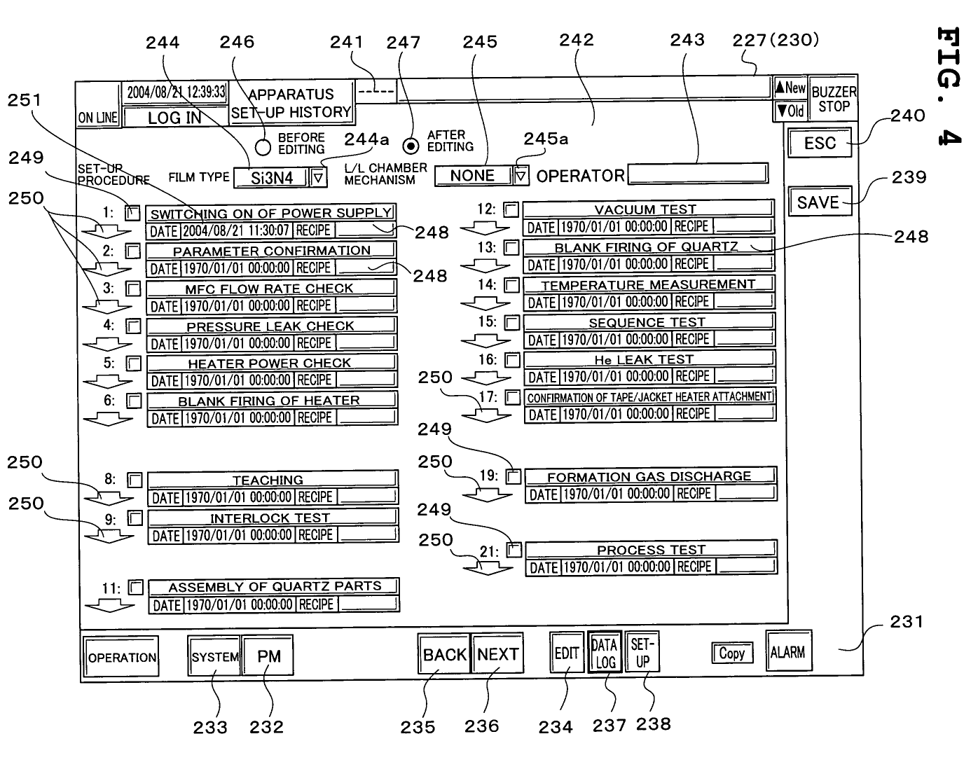

FIG. 5 is an explanatory diagram showing the operator manual listing screen in one embodiment of the present invention;

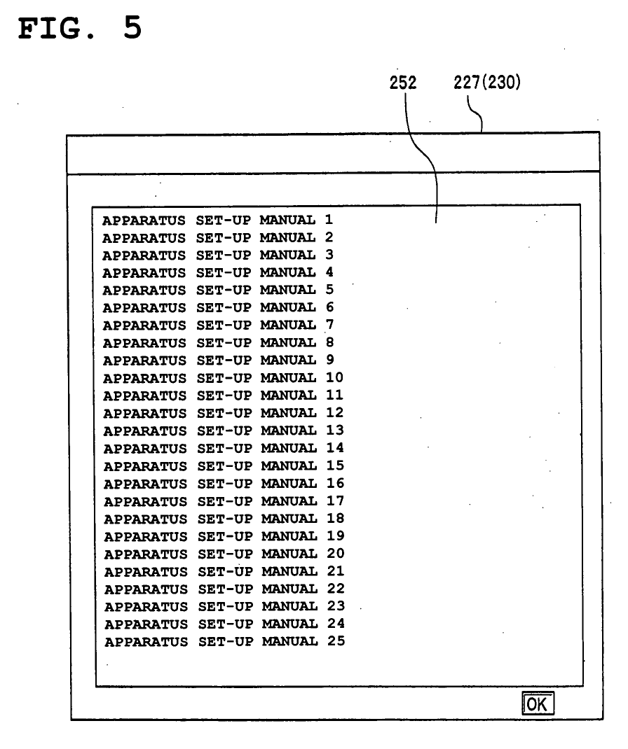

FIG. 6 is a block diagram showing the screen processing performed by the control part in order to inform the operator of the conditions of progress of the operating items in one embodiment of the present invention;

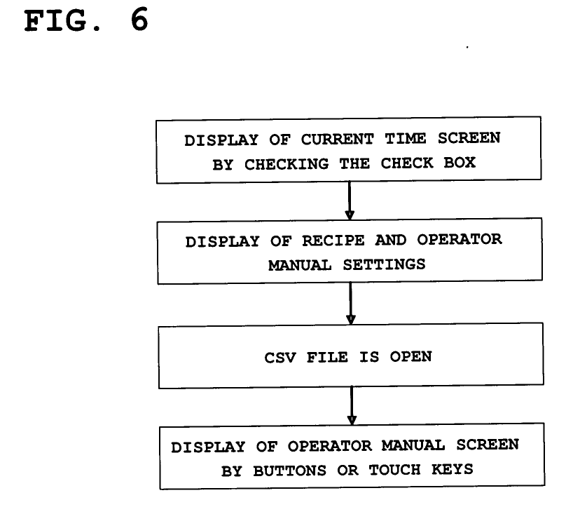

FIG. 7 is an explanatory diagram showing one example of the monitor screen showing the set-up screen, and showing the state of completion of operations for a operating item by switching of the color of the display of the degree of progress of operations according to one embodiment of the present invention;

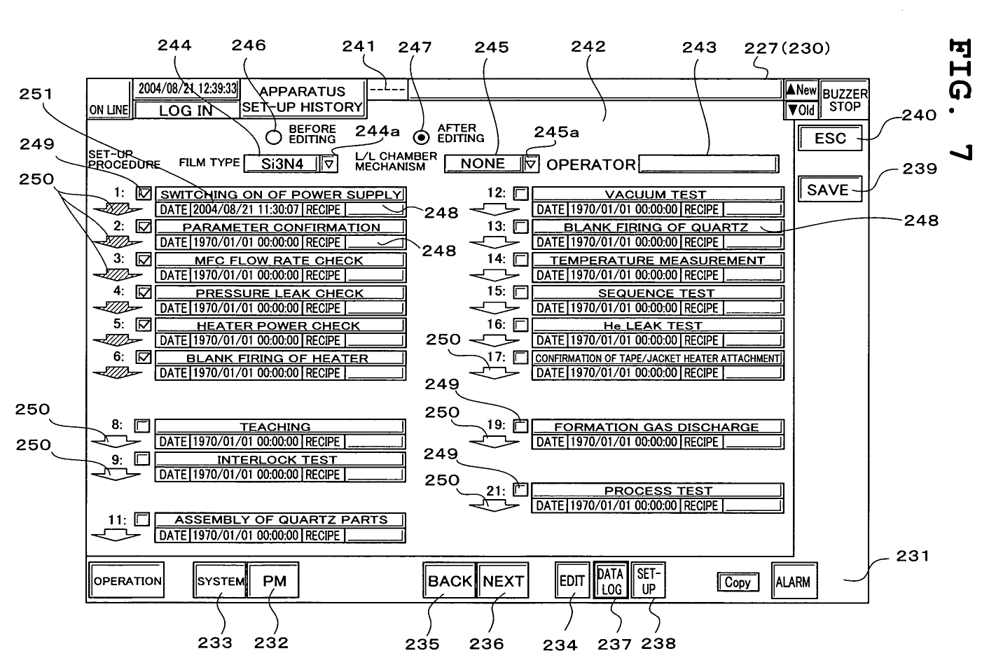

FIG. 8 is a structure diagram of the semiconductor manufacturing system for controlling the semiconductor manufacturing apparatuses in one embodiment of the present invention; and

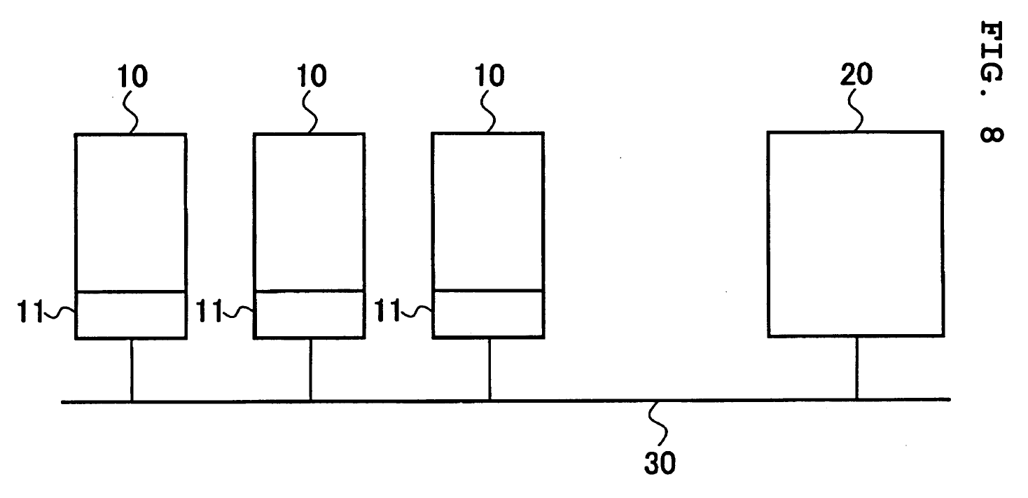

FIG. 9 is a block diagram showing the structure of the concentrated control device in one embodiment of the present invention.

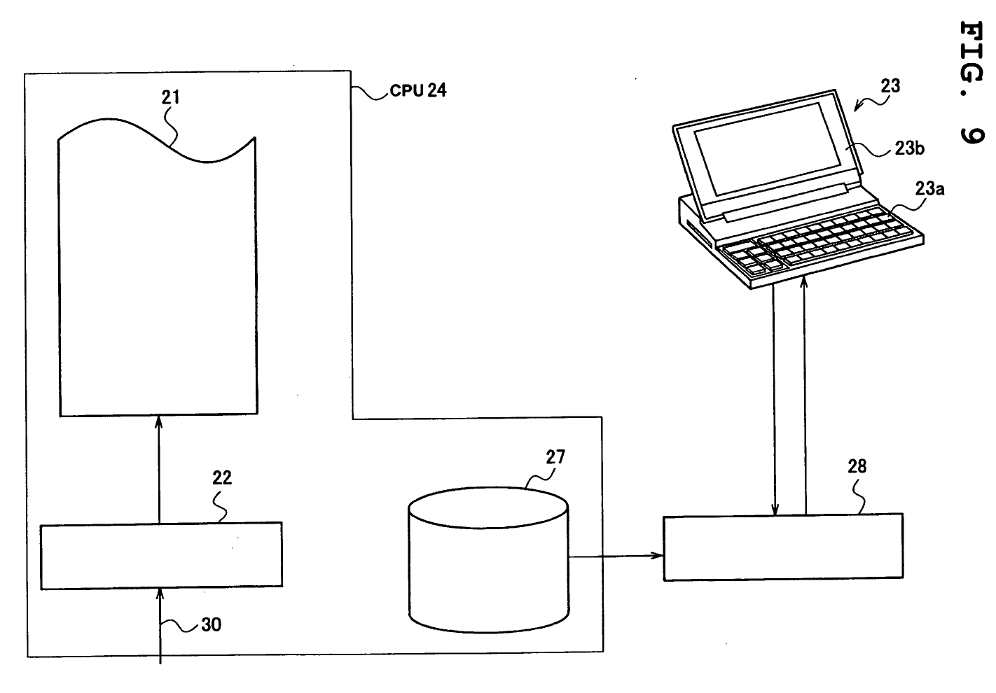

### KEY

227 Monitor

222 Control part (processing means)

1. A substrate processing apparatus in which substrates are processed by an operator who prepares recipes on an operating screen displayed on a display means, and a processing means that performs the prepared recipes, the substrate processing apparatus being constructed so that a plurality of operating items relating to an adjustment operation involving said substrate processing apparatus is displayed in order, and the recipes that are used in said respective operating items during said adjustment operations are displayed on said operating screen.

2. A substrate processing apparatus in which substrates are processed by an operator who prepares recipes on an operating screen displayed on a display means, and a processing means that performs the prepared recipes, the substrate processing apparatus being constructed so that a plurality of operating items relating to an adjustment operation involving said substrate processing apparatus is displayed in order, and the operating items displayed on said operating screen differ according to the film type or apparatus structure.

3. A substrate processing apparatus in which substrates are processed by an operator who prepares recipes on an operating screen displayed on a display means, and a processing means that performs the prepared recipes, the substrate processing apparatus being constructed so that a plurality of operating items relating to an adjustment operation involving said substrate processing apparatus is displayed in order, said operating items form buttons, and when an input is made from the respective operating item buttons on said operating screen, manuals corresponding to these operating items are displayed.

4. A substrate processing system which is constructed from a substrate processing apparatus that processes substrates, and a concentrated control device that is connected to at least one substrate processing apparatus, the substrate processing system being configured so that a plurality of operating items relating to an adjustment operation involving said substrate processing apparatus is displayed in order on the operating screen of said concentrated control device, and the recipes that are used in said respective operating items when said adjustment operations are performed are displayed on the operating screen of said concentrated control device.

5. A substrate processing system which is constructed from a substrate processing apparatus that processes substrates, and a concentrated control device that is connected to at least one substrate processing apparatus, the substrate processing system being configured so that a plurality of operating items relating to an adjustment operation involving said substrate processing apparatus is displayed in order on the operating screen of said concentrated control device, and the operating items displayed on the operating screen of said concentrated control device differ according to the film type or apparatus structure.
